(19) United States
(12) Patent Application Publication
(10) Pub. No.: US 2026/0148942 A1
(43) Pub. Date: May 28, 2026

(54) SUBSTRATE TREATING APPARATUS

(71) Applicant: SAMSUNG ELECTRONICS CO., LTD., Suwon-si (KR)

(72) Inventors: Yeong Jun LIM, Suwon-si (KR); Hyeong Mo KANG, Suwon-si (KR); Ill Sang KO, Suwon-si (KR); Sun Jin KIM, Suwon-si (KR); Ji Mo LEE, Suwon-si (KR); Dong Hyeon NA, Suwon-si (KR); Chang Gil SON, Suwon-si (KR); Sang-Ho LEE, Suwon-si (KR); Kang Min JEON, Suwon-si (KR)

(73) Assignee: SAMSUNG ELECTRONICS CO., LTD., Suwon-si (KR)

(21) Appl. No.: 19/278,178

(22) Filed: Jul. 23, 2025

(30) Foreign Application Priority Data
Nov. 26, 2024 (KR) 10-2024-0171346

(51) Int. Cl. H01J 37/32

(52) U.S. Cl. CPC H01J 37/32642; H01J 37/32715; H01J 2237/334

(57) ABSTRACT

Provided is a substrate treating apparatus including: a chamber housing; a substrate support in the chamber housing and configured to support a substrate, wherein the substrate support includes a focus ring surrounding a space configured to support the substrate; a process gas supply configured to supply a process gas into the chamber housing; and a plasma generator configured to generate plasma using an electrode in the chamber housing, wherein the focus ring includes: a second partial ring; a first partial ring on the second partial ring, the first partial ring including an inclined surface; and a third partial ring on the second partial ring and spaced apart from the first partial ring.

### CROSS-REFERENCE TO RELATED APPLICATION

This application claims priority to Korean Patent Application No. 10-2024-0171346, filed on Nov. 26, 2024 in the Korean Intellectual Property Office, the contents of which are herein incorporated by reference in its entirety.

### BACKGROUND

### 1. Field

The present disclosure relates to an apparatus installed in a semiconductor manufacturing plant that is configured to treat a substrate.

### 2. Description of Related Art

When a substrate is treated using a plasma source, uneven distribution due to discontinuity occurs frequently in an edge area of the substrate. Thus, a substrate treating apparatus using a plasma source includes a focus ring disposed around an electrostatic chuck to control distribution.

However, the focus ring may be deformed due to the influence of plasma during a process, and thus, a process shift in which a skew of critical dimension (SCD) changes. Since the change over time of the process shift has a great influence on the yield, it is necessary to control the change.

### SUMMARY

Provided is a substrate treating apparatus capable of improving SCD sensitivity and improving an etch rate in an edge area of a substrate.

According to an aspect of the disclosure, a substrate treating apparatus includes: a chamber housing; a substrate support in the chamber housing and configured to support a substrate, wherein the substrate support comprises a focus ring surrounding a space configured to support the substrate; a process gas supply configured to supply a process gas into the chamber housing; and a plasma generator configured to generate plasma using an electrode in the chamber housing, wherein the focus ring comprises: a second partial ring; a first partial ring on the second partial ring, the first partial ring comprising an inclined surface; and a third partial ring on the second partial ring and spaced apart from the first partial ring.

According to an aspect of the disclosure, a substrate treating apparatus includes: a chamber housing; a substrate support in the chamber housing and configured to support a substrate; a process gas supply configured to supply a process gas into the chamber housing; and a plasma generator configured to generate plasma using an electrode in the chamber housing, wherein the substrate support comprises: a base plate; a chucking plate on the base plate; and a focus ring along an edge of the chucking plate, and wherein the focus ring comprises: a second partial ring; a first partial ring on the second partial ring, the first partial ring comprising an inclined surface; and a third partial ring on the second partial ring and spaced apart from the first partial ring.

According to an aspect of the disclosure, a substrate treating apparatus includes: a chamber housing; a substrate support in the chamber housing and configured to support a substrate, wherein the substrate support comprises a focus ring surrounding a space configured to support the substrate; a process gas supply configured to supply a process gas into the chamber housing; and a plasma generator configured to generate plasma using an electrode in the chamber housing, wherein the focus ring comprises: a second partial ring; a first partial ring on the second partial ring, the first partial ring comprising an inclined surface; and a third partial ring on the second partial ring and spaced apart from the first partial ring, wherein the substrate treating apparatus further comprises a lift pin configured to vertically move the first partial ring, wherein a first spacing between the first partial ring and the second partial ring increases or decreases as the first partial ring moves vertically relative to the substrate support, wherein a second spacing between the first partial ring and the third partial ring increases or decreases as the first partial ring moves vertically relative to the substrate support, and wherein decrease change in the second spacing caused by vertical movement of the first partial ring is inversely proportional to decrease change in the first spacing caused by vertical movement of the first partial ring.

The present disclosure is not limited to the features and aspects described above, and other features and aspects of the present disclosure will be apparent from the following description.

### BRIEF DESCRIPTION OF DRAWINGS

The above and other aspects and features of the present disclosure will become more apparent by describing in detail embodiments thereof with reference to the attached drawings, in which:

FIG. 1 is a first example diagram illustrating semiconductor manufacturing equipment according to one or more embodiments of the present disclosure;

FIG. 2 is a second example diagram illustrating semiconductor manufacturing equipment according to one or more embodiments of the present disclosure;

FIG. 3 is a third example diagram illustrating semiconductor manufacturing equipment according to one or more embodiments of the present disclosure;

FIG. 4 is a first example diagram illustrating an internal structure of a substrate treating apparatus according to one or more embodiments of the present disclosure;

FIG. 5 is a second example diagram illustrating the internal structure of the substrate treating apparatus according to one or more embodiments of the present disclosure;

FIG. 6 is a third example diagram illustrating the internal structure of the substrate treating apparatus according to one or more embodiments of the present disclosure;

FIG. 7 is a fourth example diagram illustrating the internal structure of the substrate treating apparatus according to one or more embodiments of the present disclosure;

FIG. 8 is an example diagram illustrating the focus ring moving system of a substrate treating apparatus;

FIG. 9 is an example diagram illustrating the focus ring of the focus ring moving system;

FIG. 10 is a first example diagram illustrating a structure of the focus ring according to one or more embodiments of the present disclosure;

FIG. 11 is an example diagram illustrating a structure of the first partial ring of the focus ring according to one or more embodiments of the present disclosure;

FIG. 12 is a first example diagram illustrating an operating principle of the first partial ring of the focus ring according to one or more embodiments of the present disclosure;

FIG. 13 is a second example diagram illustrating an operating principle of a first partial ring of a focus ring according to one or more embodiments of the present disclosure;

FIG. 14 is an example diagram illustrating capacitance generated between partial rings of a focus ring according to one or more embodiments of the present disclosure;

FIG. 15 is a second example diagram illustrating the structure of the focus ring according to one or more embodiments of the present disclosure;

FIG. 16 is a third example diagram illustrating the structure of the focus ring according to one or more embodiments of the present disclosure;

FIG. 17 is a fourth example diagram illustrating the structure of the focus ring according to one or more embodiments of the present disclosure;

FIG. 18 is a fifth example diagram illustrating the structure of the focus ring according to one or more embodiments of the present disclosure;

FIG. 19 is a sixth example diagram illustrating the structure of the focus ring according to one or more embodiments of the present disclosure;

FIG. 20 is a seventh example diagram illustrating the structure of the focus ring according to one or more embodiments of the present disclosure; and

FIG. 21 is a partial cross-sectional view of a substrate support unit including a focus ring according to one or more embodiments of the present disclosure.

### DETAILED DESCRIPTIONS

Embodiments of the present disclosure will hereinafter be described with reference to the accompanying drawings. The same reference numerals are used for identical components in the drawings, and redundant explanations for these components are omitted.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The present disclosure relates to a substrate treating apparatus for treating a substrate using a plasma source. The substrate treating apparatus of the present disclosure may improve the problem related to change in the process shift over time due to deformation of the focus ring. The substrate treating apparatus of the present disclosure may improve an E/R (Etch Rate) in an edge area of a substrate. Hereinafter, semiconductor manufacturing equipment including a substrate treating apparatus will be described first, and then the substrate treating apparatus will be described.

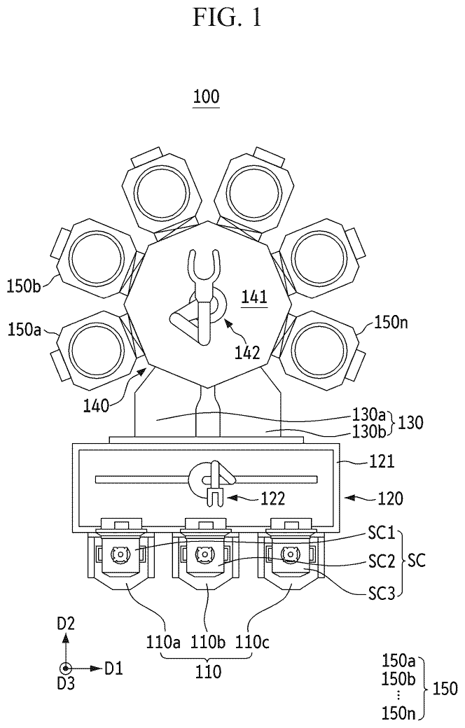

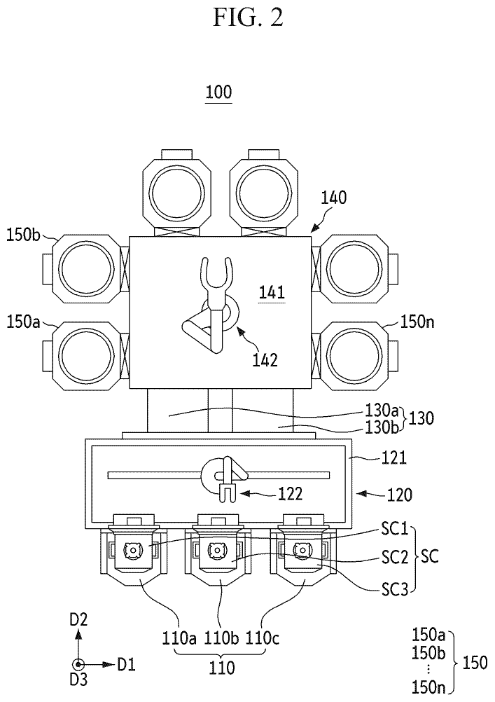

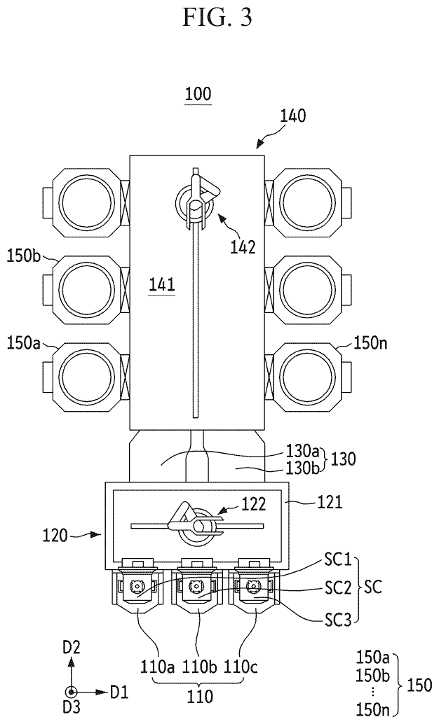

FIG. 1 is a first example diagram illustrating semiconductor manufacturing equipment according to one or more embodiments of the present disclosure. FIG. 2 is a second example diagram illustrating semiconductor manufacturing equipment according to one or more embodiments of the present disclosure. FIG. 3 is a third example diagram illustrating semiconductor manufacturing equipment according to one or more embodiments of the present disclosure.

A first direction D1 and a second direction D2 may define a two-dimensional plane. The first direction D1 may be an X-axis direction, and the second direction D2 may be a Y-axis direction. The first direction D1 may be a left-right direction, and the second direction D2 may be a front-back direction. Alternatively, the first direction D1 may be a forward-backward direction, and the second direction D2 may be a left-right direction. The first direction D1, the second direction D2 and a third direction D3 may define a three-dimensional solid. The third direction D3 is a direction perpendicular to the plane defined by the first direction D1 and the second direction D2. The third direction D3 may be a Z-axis direction. The third direction D3 may be a vertical direction.

Referring to FIG. 1 to FIG. 3, semiconductor manufacturing equipment 100 may be configured to include a load port module 110, an index module 120, a buffer module 130, a transfer module 140, and a processing module 150.

The load port module 110 may provide a seat surface on which a container SC is seated. The container SC may be transported to the load port module 110 by an overhead transport apparatus or a ground-based transport apparatus. The container SC may accommodate therein a plurality of substrates. For example, the container SC may be provided as a FOUP (Front Opening Unified Pod). The overhead transport apparatus may move on a ceiling of the semiconductor manufacturing plant and transport the container SC. For example, the overhead transport apparatus may be provided as an OHT (Overhead Hoist Transport). The ground-based transport apparatus may move on a ground of the semiconductor manufacturing plant and transport the container SC. For example, the ground-based transport apparatus may be provided as an AMR (Autonomous Mobile Robot) or an AGV (Automatic Guided Vehicle).

The container SC may be loaded into or unloaded from the load port module 110. The substrates stored in the container SC may be loaded into or unloaded from the load port module 110.

A plurality of load port modules 110 may be disposed in front of the index module 120. For example, three load ports 110a, 110b, and 110c, namely, the first load port 110a, the second load port 110b, and the third load port 110c, may be disposed in front of the index module 120. The three load ports 110a, 110b, and 110c may be arranged in the horizontal direction D1. However, embodiments of the present disclosure are not limited thereto and the three load ports 110a, 110b, and 110c may be arranged in the vertical direction D3.

When the load port module 110 includes the three load ports 110a, 110b, and 110c, the containers SC respectively seated on the load ports 110a, 110b, and 110c may store therein different types of objects, respectively. For example, a first container SC1 seated on the first load port 110a may store therein a wafer-type sensor, a second container SC2 seated on the second load port 110b may store therein a substrate, and a third container SC3 seated on the third load port 110c may store therein a consumable part such as a focus ring and an edge ring. However, the present disclosure is not limited thereto, and the containers SC respectively seated on the load ports 110a, 110b, and 110c may store therein objects of the same type. Alternatively, the containers SC respectively seated on some, but not all, of the load ports among a plurality of load ports may store therein objects of the same type.

The index module 120 may be disposed between the load port module 110 and a buffer module 130. The index module 120 may be provided as an interface for substrate transfer between the load port module 110 and the buffer module 130. The index module 120 may include a first module housing 121 and the first transport robot 122. The first module housing 121 may have an atmospheric pressure (i.e., pressurized) environment in an inside thereof. The first transport robot 122 may be disposed inside the first module housing 121 and may transport the substrate in the atmospheric pressure environment. The first transport robot 122 may include a single first transport robot or a plurality of first transport robots inside the first module housing 121.

In one or more embodiments, the index module 120 may include a buffer chamber. The buffer chamber may temporarily store therein a non-treated substrate before transporting the same to the buffer module 130. The buffer chamber may temporarily store therein a treated substrate before transporting the same to the container SC on the load port module 110. The buffer chamber may include a single buffer chamber or a plurality of buffer chambers defined in an inner wall of the first module housing 121.

The semiconductor manufacturing equipment 100 may include an equipment front end module (EFEM). The equipment front end module may include the load port module 110 and the index module 120.

The buffer module 130 may be disposed between the index module 120 and the transfer module 140. The buffer module 130 may receive a buffer stage therein. The buffer stage may temporarily store therein a non-treated substrate or a treated substrate. The buffer module 130 may include a plurality of buffer modules. For example, the buffer module 130 may include a first load lock chamber 130a and a second load lock chamber 130b.

The two load lock chambers 130a and 130b may be arranged in the horizontal direction D1. However, embodiments of the present disclosure are not limited thereto, and the two load lock chambers 130a and 130b may be arranged in the vertical direction D3. The two load lock chambers 130a and 130b may be arranged in the same direction as the arrangement direction of the three load ports 110a, 110b, and 110c, or in a different direction from the arrangement direction of the three load ports 110a, 110b, and 110c.

The first load lock chamber 130a and the second load lock chamber 130b may provide different functions. For example, one of the first load lock chamber 130a and the second load lock chamber 130b may store therein non-treated substrates, while the other thereof may store therein treated substrates. However, the present disclosure is not limited thereto, and the first load lock chamber 130a and the second load lock chamber 130b may provide the same function. Each of the first load lock chamber 130a and the second load lock chamber 130b may store therein any substrate regardless of whether the substrate has been treated.

The buffer module 130 may change an inside thereof into either a vacuum environment or an atmospheric pressure environment using a gate valve. The buffer module 130 may change the inside thereof into an environment identical to or similar to an internal environment of the index module 120. When the first transport robot 122 loads the substrate into the buffer module 130 or the first transport robot 122 unloads the substrate from the buffer module 130, the buffer module 130 may perform the above function. The buffer module 130 may prevent an internal pressure state of the index module 120 from changing.

The buffer module 130 may change the inside thereof into an environment identical or similar to an internal environment of the transfer module 140. When the second transport robot 142 loads the substrate into the buffer module 130 or the second transport robot 142 unloads the substrate from the buffer module 130, the buffer module 130 may perform the above function. The buffer module 130 may prevent an internal pressure state of the transfer module 140 from changing. As will be described later, the second transport robot 142 may be located within the transfer module 140.

The transfer module 140 may be disposed between the buffer module 130 and the processing module 150. The transfer module 140 may be provided as an interface for substrate transfer between the buffer module 130 and the processing module 150. The transfer module 140 may include a second module housing 141 and the second transport robot 142. The second module housing 141 may have a vacuum environment in an inner space thereof. The second transport robot 142 may be disposed within the second module housing 141 and may transport the substrate in the vacuum environment. The second transport robot 142 may include a single second transport robot or a plurality of second transport robot disposed within the second module housing 141.

The processing module 150 may include a plurality of substrate treating apparatuses 150a, 150b,. 150n. Each of the substrate treating apparatuses 150a, 150b, . . . , 150n may perform one of an etching process, a cleaning process, a deposition process, and an ion implantation process. The plurality of substrate treating apparatuses 150a, 150b, . . . , 150n may be provided as the same type of process chamber. However, the present disclosure is not limited thereto, and the plurality of substrate treating apparatuses 150a, 150b, . . . , 150n may be provided as different types of process chambers. The processing module 150 may also include a single substrate treating apparatus.

The transfer module 140 may be connected to each of the substrate treating apparatuses 150a, 150b, . . . , 150n. The second module housing 141 may include a plurality of sides, and the second transport robot 142 may be configured to freely pivot around each of the sides of the second module housing 141 so that the second transport robot 142 may load or unload the substrate.

Each of the substrate treating apparatuses 150a, 150b, . . . , 150n may treat the non-treated substrate when the non-treated substrate has been provided thereto through the transfer module 140. Each of the substrate treating apparatuses 150a, 150b, . . . , 150n may provide the treated substrate to the transfer module 140.

The semiconductor manufacturing equipment 100 may be formed in a cluster platform structure. Referring to FIG. 1, the plurality of substrate treating apparatuses 150a, 150b, . . . , 150n may be arranged in a cluster manner around the transfer module 140. However, the present disclosure is not limited thereto, and the semiconductor manufacturing equipment 100 may be formed in a quad platform structure. Referring to FIG. 2, the plurality of substrate treating apparatuses 150a, 150b, . . . , 150n may be arranged in the quad manner around the transfer module 140. Alternatively, the semiconductor manufacturing equipment 100 may be formed in an inline platform structure. Referring to FIG. 3, the plurality of substrate treating apparatuses 150a, 150b, . . . , 150n may be arranged in an in-line manner around the transfer module 140 as shown in the example of FIG. 3, in which two arrangements of the substrate treating apparatuses may be respectively disposed on opposing sides of the transfer module 140, and the different substrate treating apparatuses in the two arrangements may face each other in a corresponding manner with each other, and each of the two arrangements may extend in a line.

The semiconductor manufacturing equipment 100 may further include a control device. The control device may control an operation of each of the modules constituting the semiconductor manufacturing equipment 100. For example, the control device may control the substrate transport operation of each of the transport robots 122 and 142, control the internal environmental change of each of the load lock chambers 130a and 130b, and control an overall substrate treatment process of each of the substrate treating apparatuses 150a, 150b, . . . , 150n.

The control device may include one or more processors that, individually or collectively, control each of the components constituting the semiconductor manufacturing equipment 100, a network over which the components communicate with each other in a wired manner or wirelessly, one or more instructions related to a function or an operation for controlling each of the components, a memory means that stores therein treating recipes including instructions, various data, etc. The control device may further include a user interface including an input means for an operator to perform command input manipulation, etc. to manage the semiconductor manufacturing equipment 100, and an output means for visualizing and displaying the operating status of the semiconductor manufacturing equipment 100. The control device may be embodied as a computing device for data processing and analysis, command transmission, etc.

The instructions may be provided in a form of a computer program or an application. The computer program may be stored in a computer-readable recording medium containing one or more instructions. The instructions may include codes generated by a compiler, codes that may be executed by an interpreter, etc. The memory may be embodied as one or more storage media selected from flash memory, HDD, SSD, card type memory, RAM, SRAM, ROM, EEPROM, PROM, magnetic memory, magnetic disk, and optical disk.

Next, the plurality of substrate treating apparatuses 150a, 150b, . . . , 150n will be described. Hereinafter, an embodiment in which the plurality of substrate treating apparatuses 150a, 150b, . . . , 150n are provided as the same type of process chamber, and each of the substrate treating apparatuses 150a, 150b, . . . , 150n treats the substrate using an etching process, will be described. However, the present disclosure is not limited thereto, and at least one substrate treating apparatus among the remaining substrate treating apparatuses, except for the first substrate treating apparatus 150a, may treat the substrate using one of a cleaning process, a deposition process, and an ion implantation process.

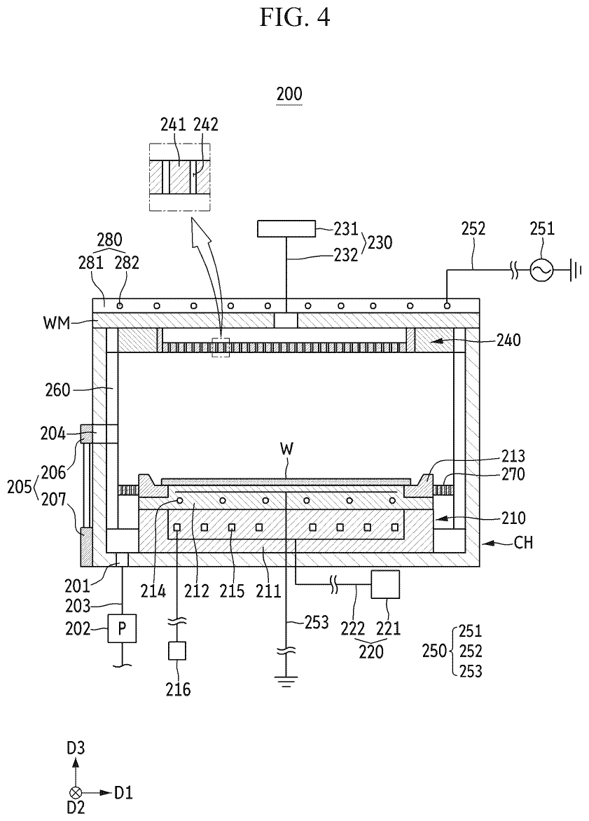

FIG. 4 is a first example diagram illustrating an internal structure of a substrate treating apparatus according to one or more embodiments of the present disclosure. The first substrate treating apparatus 150a may be provided as a process chamber 200 for treating the substrate using plasma. The process chamber 200 may treat the substrate using plasma. The process chamber 200 may treat the substrate in a vacuum environment. Referring to FIG. 4, the process chamber 200 may be configured to include a chamber housing CH, a substrate support 210, a cleaning gas supply 220, a process gas supply 230, a showerhead 240, a plasma generator 250, a liner 260, a baffle 270, a window module WM and an antenna 280.

The chamber housing CH provides a space where a process for treating the substrate W using plasma, i.e., a plasma process, is performed. The chamber housing CH may be made of alumite having an anodic oxide film formed on its surface, and an inner space thereof may be configured to be airtight. The chamber housing CH may be provided in a cylindrical shape. However, the present disclosure is not limited thereto, and the chamber housing CH may be provided in other shapes. The chamber housing CH may have an exhaust hole 201 defined in a bottom thereof.

The exhaust hole 201 may be connected to an exhaust line 203 equipped with a pump 202. The exhaust hole 201 may discharge to the outside out of the chamber housing CH, through the exhaust line 203, reaction byproducts generated during the plasma process and gases remaining inside the chamber housing CH. The inner space of the chamber housing CH may be depressurized through the discharge of gases through the exhaust hole 201.

An opening 204 may extend through a side wall of the chamber housing CH. The opening 204 may act as a passage through which the substrate W enters and exits the inside of the chamber housing CH. The opening 204 may be configured to be automatically opened and closed by, for example, a door assembly 205.

The door assembly 205 may be configured to include an outer door 206 and a door driver 207. The outer door 206 may open and close the opening 204 while being disposed on an outer wall of the chamber housing CH. The outer door 206 may be moved in the vertical direction D3 of the process chamber 200 under control of the door driver 207. The door driver 207 may operate using at least one element selected from a motor, a hydraulic cylinder, and a pneumatic cylinder; however, the disclosure is not limited thereto, and other methods of opening and closing the outer door 206 may be applied.

The substrate support 210 is installed in a lower area of the inner space of the chamber housing CH. The substrate support 210 may adhere to, secure, and support the substrate W using an electrostatic force. For example, the substrate support 210 may be embodied as an electrostatic chuck (ESC). However, the present disclosure is not limited thereto, and the substrate support 210 may support the substrate W thereon using various other schemes such as vacuum, mechanical clamping, etc.

When the substrate support 210 is embodied as the electrostatic chuck (ESC), the substrate support 210 may be configured to include a base plate 211 and a chucking plate 212. The chucking plate 212 may be disposed on the base plate 211 and may adhere to, secure, and support the substrate W that is placed thereon. The base plate 211 may be made of a material having excellent corrosion resistance and heat resistance. For example, the base plate 211 may be an aluminum plate. For example, the chucking plate 212 may be a ceramic puck.

The substrate support 210 may be configured to further include a bonding layer. The bonding layer may bond the base plate 211 and the chucking plate 212 to each other. The bonding layer may include, for example, a polymer.

A focus ring 213 is provided to surround an outer edge area of the chucking plate 212. The focus ring 213 may play a role in concentrating ions on the substrate W when the plasma process is performed inside the chamber housing CH. The focus ring 213 may be made of silicon.

The substrate support 210 may further include an edge ring. The substrate support 210 may include a ring structure composed of the focus ring 213 and the edge ring. The edge ring may cover an outer surface of the focus ring 213. The edge ring may prevent the focus ring 213 from being etched. The edge ring may cover the outer surfaces of the base plate 211 and the chucking plate 212 as well as the focus ring 213. The edge ring may prevent the side surfaces of the base plate 211 and the chucking plate 212 from being damaged by the plasma. The edge ring may be made of an insulator material. For example, the edge ring may be made of quartz or ceramic.

A heating member 214 and a cooling member 215 may be provided to maintain the substrate W at a process temperature when the substrate treating process is performed inside the chamber housing CH. The heating member 214 may be installed inside the chucking plate 212 and may be embodied as a heating wire. The cooling member 215 may be installed inside the base plate 211 and may be embodied as a cooling pipe through which a coolant flows. A cooling device or a chiller 216 may supply the coolant to the cooling member 215. The cooling device 216 may use cooling water as the coolant. However, the present disclosure is not limited thereto, and helium (He) gas may be used as the coolant. Alternatively, the cooling device 216 may use both cooling water and helium gas as the coolant. In one example, the substrate support 210 may not include the heating member 214.

The cleaning gas supply 220 provides a cleaning gas onto the chucking plate 212 or the focus ring 213 to remove foreign substances remaining on the chucking plate 212 or the focus ring 213. For example, the cleaning gas supply 220 may provide nitrogen (N₂) gas as the cleaning gas.

The cleaning gas supply 220 may include a cleaning gas supply source 221 and a cleaning gas supply pipe 222. The cleaning gas supply pipe 222 may be connected to a space between the chucking plate 212 and the focus ring 213. The cleaning gas supplied from the cleaning gas supply source 221 may flow to the space between the chucking plate 212 and the focus ring 213 through the cleaning gas supply pipe 222 to remove the foreign substances remaining on an edge portion of the chucking plate 212 or an upper portion of the focus ring 213.

The process gas supply 230 provides process gas to the inner space of the chamber housing CH. The process gas supply 230 may provide process gas to the inner space of the chamber housing CH through a hole extending through an upper cover, for example, the window module WM of the chamber housing CH. However, the present disclosure is not limited thereto, and the process gas supply 230 may provide the process gas to the inner space of the chamber housing CH through a hole extending through a side wall of the chamber housing CH.

The process gas supply 230 may include a process gas supply source 231 and a process gas supply pipe 232. The process gas supply source 231 may provide process gas used to treat the substrate W. The process gas supply source 231 may be provided as a single process gas supply source in the process chamber 200. However, the present disclosure is not limited thereto and the process chamber 200 may include a plurality of process gas supply sources. In a case where the process chamber 200 includes a plurality of process gas supply sources 231, the plurality of process gas supply sources 231 may provide the same type of process gas. However, the present disclosure is not limited thereto and the plurality of process gas supply sources 231 may provide different types of process gases.

The showerhead 240 sprays the process gas provided from the process gas supply source 231 to an entire area of the substrate W placed in the inner space of the chamber housing CH. The showerhead 240 may be connected to the process gas supply source 231 via the process gas supply pipe 232.

The showerhead 240 may be disposed in the inner space of the chamber housing CH and may include a showerhead body 241 and a plurality of gas feeding holes 242. The showerhead body 241 may be made of silicon. However, the present disclosure is not limited thereto and the showerhead body 241 may be made of metal. The plurality of gas feeding holes 242 may extend through a surface of the showerhead body 241 in the vertical direction D3. The plurality of gas feeding holes 242 may be spaced apart from each other by a predetermined spacing and may extend through the showerhead body 241. The plurality of gas feeding holes 242 may uniformly inject the process gas onto the entire area of the substrate W.

The showerhead 240 may be installed within the chamber housing CH so as to face the substrate support 210 in the vertical direction D3. The showerhead 240 may be constructed to have a diameter larger than that of the chucking plate 212. However, the present disclosure is not limited thereto. The showerhead 240 may be constructed to have the diameter equal to the diameter of the chucking plate 212. The showerhead 240 may be made of silicon. However, the present disclosure is not limited thereto and the showerhead 240 may be made of metal.

In one or more embodiments, the showerhead 240 may be divided into a plurality of modules. For example, the showerhead 240 may be divided into three modules including a first head module, a second head module, and a third head module. The first head module may be disposed at a position corresponding to or overlapping a center area of the substrate W. The second head module may be disposed to surround an outer edge of the first head module. The second head module may be disposed at a position corresponding to or overlapping a middle area of the substrate W. The third head module may be disposed to surround an outer edge of the second head module. The third head module may be disposed at a position corresponding to or overlapping an edge area of the substrate W.

The plasma generator 250 may generate plasma from gas remaining in a discharge space. The discharge space may be surrounded by the showerhead 240 and the window module WM. Alternatively, the discharge space may be a space defined between the substrate support 210 and the showerhead 240 in the chamber housing CH. When the discharge space is a space defined between the substrate support 210 and the showerhead 240, the discharge space may be divided into a plasma area and a process area. The plasma area may be positioned on top of the process area.

The plasma generator 250 may generate plasma in the discharge space using an inductively coupled plasma (ICP) source. The plasma generator 250 may generate plasma in the discharge space using the substrate support 210 and the antenna 280 as lower and upper electrodes, respectively. However, the present disclosure is not limited thereto, and the plasma generator 250 may generate plasma in the discharge space using a capacitively coupled plasma (CCP) source. For example, the plasma generator 250 may generate plasma in the discharge space using the substrate support 210 and the showerhead 240 as lower and upper electrodes, respectively. A case in which the plasma generator 250 generates the plasma in the discharge space using the CCP source will be described later.

The plasma generator 250 may include a first high frequency power source 251, a first transmission line 252, and a second transmission line 253. The first high frequency power supply 251 applies radio frequency (RF) power to the upper electrode. For example, the first high frequency power source 251 may provide a high frequency signal of 2 MHz to 40 MHz. The first high-frequency power supply 251 may serve as a plasma source for generating plasma in the chamber housing CH. The first high-frequency power supply 251 may serve to control characteristics of plasma in the chamber housing CH. The first high frequency power source 251 may serve to adjust ion bombardment energy in the chamber housing CH.

A plurality of first high frequency power sources 251 may be provided in the process chamber 200. The plasma generator 250 may include a first matching network electrically connected to each first high-frequency power source. When high frequency power of different magnitudes is respectively input to the first matching network from the plurality of first high frequency power sources, the first matching network may match the high frequency power with each other and apply the matching result to the upper electrode.

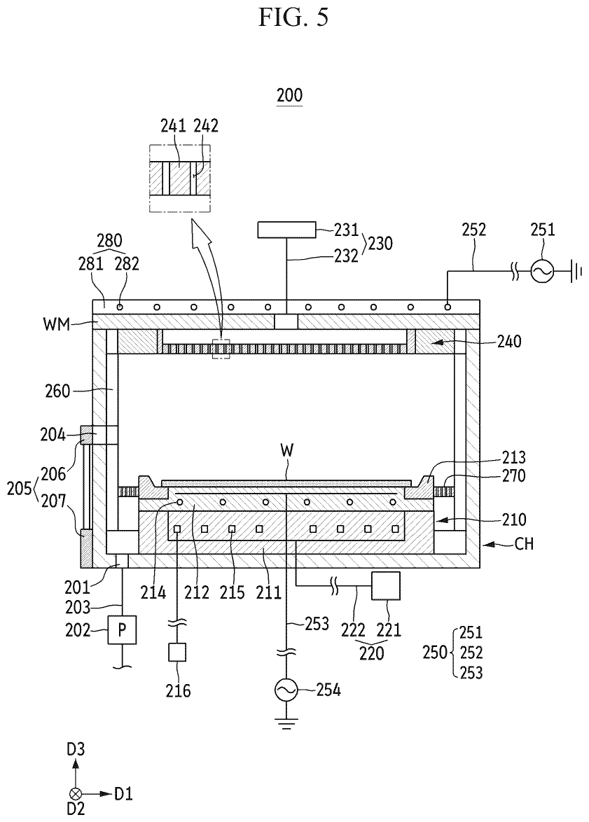

The first transmission line 252 may connect the upper electrode to the first high frequency power source 251. The first transmission line 252 may connect the first high-frequency power source 251 and the GND to each other. The second transmission line 253 may connect the lower electrode and the GND to each other. A high frequency power source may not be installed at the second transmission line 253. For example, the second transmission line 253 may be provided as an RF rod. However, the present disclosure is not limited thereto, and referring to FIG. 5, the second high frequency power source 254 may be installed at the second transmission line 253. The second transmission line 253 may connect the second high-frequency power source 254 to each of the lower electrode and the GND. FIG. 5 is a second example diagram illustrating the internal structure of the substrate treating apparatus according to one or more embodiments of the present disclosure.

The second high frequency power source 254 applies RF power to the lower electrode. For example, the second high frequency power source 254 may provide a high frequency signal of 20 MHz to 100 MHz. A plurality of second high frequency power sources 254 may be provided in the process chamber 200. In this case, the plasma generator 250 may include a second matching network electrically connected to each of the second high-frequency power sources. When high frequency power of different magnitudes is respectively input to the second matching network from the plurality of second high frequency power sources, the second matching network may match the high frequency power with each other and apply a matching result to the upper electrode. When the plasma generator 250 includes the first high frequency power source 251 and the second high frequency power source 254, a multi-frequency may be applied to the process chamber 200.

The present disclosure will be described again with reference to FIG. 4.

The liner 260 may be defined as a wall liner, and is configured to protect the inside of the chamber housing CH from arc discharge generated during the process of exciting the process gas or caused by impurities generated during the substrate treatment process. The liner 260 may be formed to cover the inner wall of the chamber housing CH.

The baffle 270 serves to exhaust process by-products of plasma, unreacted gas, or the like in the chamber housing CH to the outside. The baffle 270 may be installed in a space between the substrate support 210 and the inner wall (or the liner 260) of the chamber housing CH, and may be installed adjacent to the exhaust hole 201. The baffle 270 may be provided in an annular ring shape and be disposed between the substrate support 210 and the inner wall of the chamber housing CH.

The baffle 270 may include a plurality of slot holes extending through the body of the baffle 270 in the vertical direction D3 to control the flow of the process gas in the chamber housing CH. The baffle 270 may be made of a material having etch resistance in order to minimize damage or deformation due to radicals or the like in the inner space of the chamber housing CH in which plasma is generated. For example, the baffle 270 may include quartz.

The window module WM serves as an upper cover of the chamber housing CH that seals the inner space of the chamber housing CH. The window module WM may be provided in a separate manner from the chamber housing CH. However, the present disclosure is not limited thereto, and the window module WM may be formed integrally with the chamber housing CH. The window module WM may be made of an insulating material and thus may act as a dielectric window. For example, the window module WM may be formed using alumina. The window module WM may include a coating film on a surface thereof to suppress generation of particles when a plasma process is performed in the inner space of the chamber housing CH.

The antenna 280 generates a magnetic field and an electric field in the chamber housing CH to excite the process gas into plasma. The antenna 280 may operate using RF power supplied from the first high frequency power source 251. The antenna 280 may be provided on top of the chamber housing CH. For example, the antenna 280 may be provided on top of the window module WM. However, the present disclosure is not limited thereto, and the antenna 280 may be provided to surround the sidewall of the chamber housing CH.

The antenna 280 may include an antenna pattern 282 inside or on the surface of the antenna body 281. The antenna pattern 282 may be provided to form a closed loop using a coil. The antenna pattern 282 may be formed in a spiral shape or various other shapes along a width direction D1 of the chamber housing CH.

The antenna 280 may be formed to have a planar structure. However, the present disclosure is not limited thereto, and the antenna 280 may be formed to have a cylindrical structure. When the antenna 280 is formed to have a planar structure, the antenna may be provided on top of the chamber housing CH. When the antenna 280 is formed to have the cylindrical structure, the antenna may be provided to surround the sidewall of the chamber housing CH.

Next, a case in which the plasma generator 250 generates plasma using the CCP source will be described. Hereinafter, the description of the contents duplicate with those as described above with reference to the case of FIGS. 4 and 5 will be omitted, and only the difference therebetween will be described. When the plasma generator 250 generates the plasma using the CCP source, the showerhead 240 may act as an upper electrode. However, the present disclosure is not limited thereto, and a separate upper electrode may be provided in the process chamber 200. For example, the upper electrode may be provided adjacent to the window module WM.

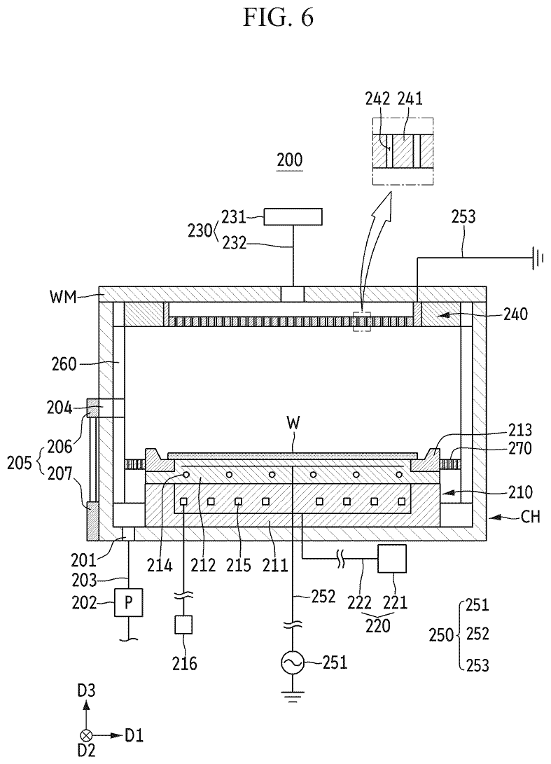

Referring to FIG. 6, the plasma generator 250 may include the first high frequency power source 251, the first transmission line 252, and the second transmission line 253. The first high frequency power source 251 may apply RF power to the lower electrode. The first transmission line 252 may connect the lower electrode to the first high-frequency power source 251. The first transmission line 252 may connect the first high-frequency power source 251 and the GND to each other. The second transmission line 253 may connect the upper electrode to GND. FIG. 6 is a third example diagram illustrating the internal structure of the substrate treating apparatus according to one or more embodiments of the present disclosure.

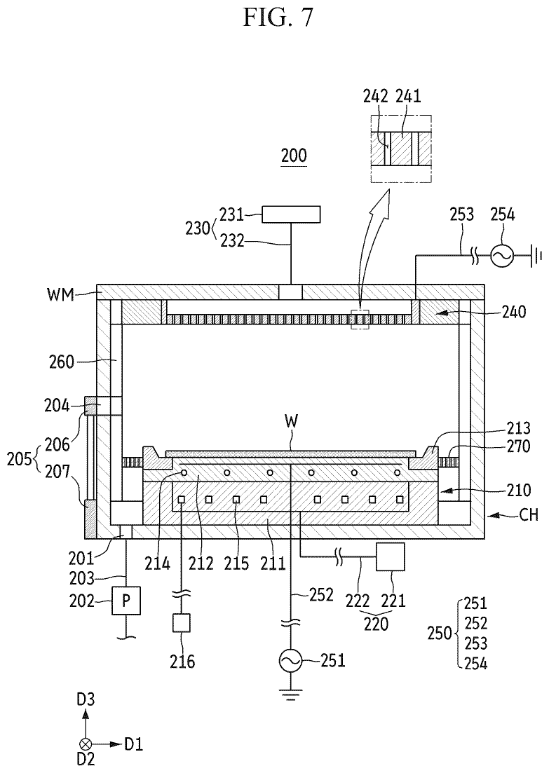

Referring to FIG. 7, the plasma generator 250 may further include the second high frequency power source 254. The second high frequency power source 254 may apply RF power to the upper electrode. The second transmission line 253 may connect the upper electrode to the second high-frequency power source 254. The second transmission line 253 may connect the second high-frequency power source 254 and the GND to each other. FIG. 7 is a fourth example diagram illustrating the internal structure of the substrate treating apparatus according to one or more embodiments of the present disclosure.

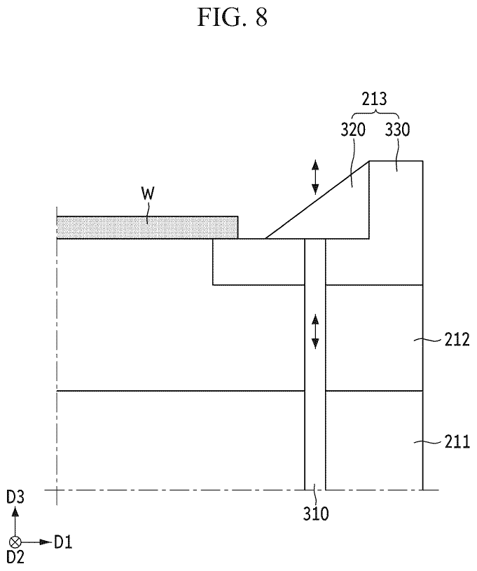

As described above, when the focus ring 213 is deformed, a change in the process shift over time may occur. In order to control the change of the process shift over time, a focus ring movement system may be applied to the process chamber 200. FIG. 8 is an example diagram illustrating the focus ring moving system included in a substrate treating apparatus.

Referring to FIG. 8, the process chamber 200 may further include a lift pin 310. The lift pin 310 may vertically move the focus ring 213. The lift pin 310 may sequentially pass through the base plate 211 and the chucking plate 212 in the third direction D3. The lift pin 310 may, or may not, be in contact with the bottom surface of the focus ring 213. Alternatively, the lift pin 310 may be coupled to the focus ring 213. The vertical movement of the focus ring 213 may be associated with the vertical movement of the lift pin 310.

The lift pin 310 may vertically move the entire focus ring 213. However, in one or more embodiments, in order to prevent the chucking plate 212 and prevent the chucking plate 212 from being etched, the lift pin 310 raises and lowers a portion of the focus ring 213.

A shape of the focus ring 213 may affect a sheath thickness to determine an ion incident angle in an edge area of the substrate W, and may adjust a Skew of Critical Dimension (SCD) value as a spacing between centers of the upper and lower ends of the pattern during the substrate treating process. In addition, the coupling voltage of the focus ring 213 may be involved in ion energy to affect the etch rate E/R in the edge area of the substrate W. Therefore, in a high aspect ratio contact (HARC) etching process, optimization of the shape of the focus ring 213 is a very important factor for process improvement and control of a change over time.

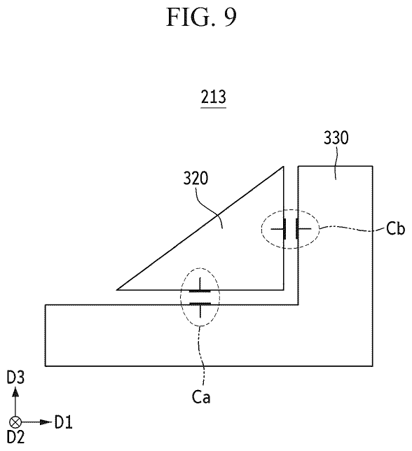

However, when the focus ring 213 has the structure as shown in FIG. 8, the following problems may occur. First, the SCD change sensitivity when the focus ring 213 is vertically moved may be unstable. Referring to FIG. 9, an a-th capacitance Ca and an b-th capacitance Cb may be generated between an a-th portion 320 and a b-th portion 330 of the focus ring 213. Specifically, the a-th capacitance Ca may be generated between the lower surface of the b-th portion 320 and the upper surface of the a-th portion 330, and the a-th capacitance Cb may be generated between the side surface of the b-th portion 320 and the side surface of the b-th portion 330. FIG. 9 is an example diagram illustrating the focus ring included in the focus ring moving system.

As described above, where the focus ring 213 has a structure such as that shown in FIGS. 8 and 9, when the focus ring 213 moves upwardly, the b-th capacitance Cb may maintain a constant value, while the a-th capacitance Ca may decrease. Accordingly, a total capacitance acting on the focus ring 213 may be reduced nonlinearly, and the SCD value may also be changed nonlinearly. Since the capacitance changes rapidly based on the extent to which the focus ring 213 moves upwardly, and the variation in the SCD sensitivity is large, it is impossible to precisely control the focus ring 213 according to the change of the process shift over time.

Second, due to a coupling voltage drop of the focus ring 213, process deterioration may occur in the edge area of the substrate W. When the focus ring 213 moves upwardly, the total capacitance acting on the focus ring 213 decreases, and the coupling voltage of the focus ring 213 also decreases. Accordingly, an etch rate in the edge area of the substrate W may be reduced, and process deterioration such as ENO (edge not open) may occur.

The shape and the dimension of the focus ring 213 are the main design considerations regarding the focus ring 213 when determining the total capacitance and the sheath thickness of the focus ring 213, which may in turn determine the etch rate and the ion incidence angle in the edge area of the substrate W. Hereinafter, the focus ring 213 having an equipotential structure will be described. When the focus ring 213 has an equipotential structure, the problem of the SCD change sensitivity becoming unstable as the focus ring 213 moves upwardly and downwardly may be solved. In addition, when the focus ring 213 has an equipotential structure, a problem in which process deterioration occurs in the edge area of the substrate W due to the coupling voltage drop of the focus ring 213 may also be solved. The focus ring 213 having an equipotential structure may obtain an effect of efficiently controlling the change of the process shift over time, and may also obtain an effect of securing a process margin.

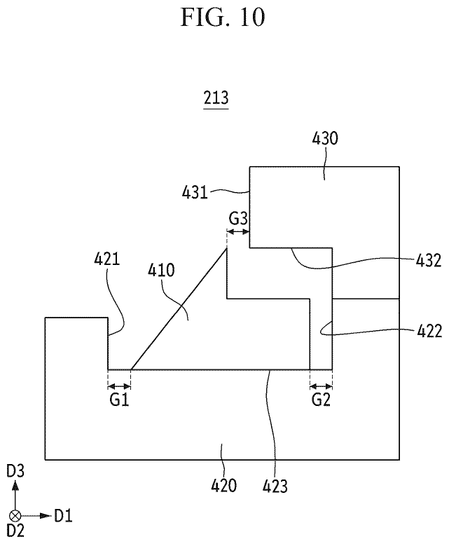

FIG. 10 is a first example diagram illustrating a structure of the focus ring according to one or more embodiments of the present disclosure. The focus ring 213 may be provided as a ring-shaped structure. The focus ring 213 may cover an edge area on the chucking plate 212. The substrate W may be disposed in a space surrounded with the focus ring 213. The focus ring 213 may surround the substrate W having a disk shape.

The focus ring 213 may protrude in the third direction D3 beyond the upper surface of the chucking plate 212. The focus ring 213 may partially cover a side surface of the chucking plate 212. However, the present disclosure is not limited thereto, and the focus ring 213 may cover the entire side surface of the chucking plate 212. Referring to FIG. 10, the focus ring 213 may include a first partial ring 410, a second partial ring 420, and a third partial ring 430. FIG. 10 shows a cross-sectional shape of one side of the focus ring 213. It will be noted that in FIG. 10, the structure of the focus ring 213 is described based on the cross-sectional shape of the focus ring 213.

The first partial ring 410 may be provided as an inner focus ring. The first partial ring 410 may be disposed in a space surrounded with the second partial ring 420 and the third partial ring 430. The second partial ring 420 may support a lower portion of the first partial ring 410, and the third partial ring 430 may cover an upper portion of the first partial ring 410. The first partial ring 410 may be disposed between the second partial ring 420 and the third partial ring 430.

The second partial ring 420 may be provided as an under focus ring. The second partial ring 420 may support not only the first partial ring 410 but also the third partial ring 430. The second partial ring 420 may include a recessed (or concave-convex) structure. The first partial ring 410 may be disposed on a recessed portion of the second partial ring 420. The second partial ring 420 may not include the recessed structure. In this case, the first partial ring 410 may be disposed on a flat surface of the second partial ring 420. When the second partial ring 420 includes the recessed structure, the third partial ring 430 may be supported by a vertical extension of the second partial ring 420.

The third partial ring 430 may be provided as an upper focus ring. The third partial ring 430 may include a bent structure. The third partial ring 430 may be formed in a structure in which the ring is bent twice or more. The third partial ring 430 having this structure may be formed to cover the upper portion of the first partial ring 410. The third partial ring 430 may cover a portion of an upper portion of the first partial ring 410. The third partial ring 430 may cover the entire upper portion of the first partial ring 410. The third partial ring 430 may not be in contact with an upper portion of the first partial ring 410. A bottom surface of the third partial ring 430 may be spaced apart from the upper portion of the first partial ring 410. Since a spacing is defined between the first partial ring 410 and the third partial ring 430, the first partial ring 410 can be raised and lowered.

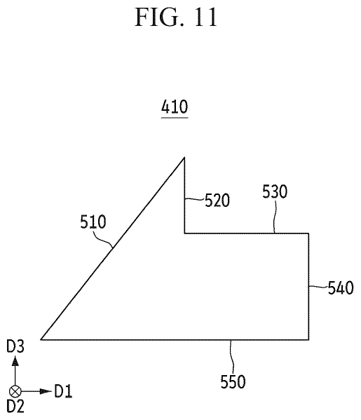

FIG. 11 is an example diagram illustrating a structure of the first partial ring included in the focus ring according to one or more embodiments of the present disclosure. Referring to FIG. 11, the first partial ring 410 may include a first surface 510, a second surface 520, a third surface 530, a fourth surface 540, and a fifth surface 550. The following description refers to FIG. 10 and FIG. 11.

The first surface 510 may be provided to have an inclined structure in the third direction D3. When a direction parallel to the first direction D1 or the second direction D2 is defined as 0 degree and a direction parallel to the third direction D3 is defined as 90 degrees, the inclination angle of the first surface 510 may be greater than 0 degree and smaller than 90 degrees. The first surface 510 may be oriented to face toward the substrate W in the process chamber 200. The first surface 510 may be adjacent to the second partial ring 420. The first surface 510 may be adjacent to the first surface 421 as an inner surface of the second partial ring 420. The first surface 510 may not be in contact with the second partial ring 420. The first surface 510 may be spaced apart from the second partial ring 420. The first surface 510 may be spaced apart from the second partial ring 420 by a first spacing G1.

The second surface 520 may be connected to the first surface 510. The second surface 520 may extend so as to have a longitudinal direction parallel to the third direction D3. The second surface 520 may be adjacent to the third partial ring 430. The second surface 520 may be adjacent to a first surface 431 as an outer surface of the third partial ring 430. The second surface 520 may not be in contact with the third partial ring 430. The second surface 520 may be spaced apart from the third partial ring 430. The second surface 520 may be spaced apart from the third partial ring 430 by a third spacing G3.

The third surface 530 may be connected to the second surface 520. The third surface 530 may extend as to have a longitudinal direction parallel to the first direction D1 or the second direction D2. The third surface 530 may be adjacent to the third partial ring 430. The third surface 530 may be adjacent to a second surface 432 as a lower inner surface of the third partial ring 430. The third surface 530 may not be in contact with the third partial ring 430. The third surface 530 may be spaced apart from the third partial ring 430. The second surface 520 and the third surface 530 may be spaced apart from the third partial ring 430, thereby allowing the first partial ring 410 to vertically move.

The fourth surface 540 may be connected to the third surface 530. The fourth surface 540 may extend so as to have a longitudinal direction parallel to the third direction D3. The fourth surface 540 may be adjacent to the second partial ring 420. Alternatively, the fourth surface 540 may be adjacent to the second partial ring 420 and the third partial ring 430. The fourth surface 540 may be adjacent to a second surface 422 as an inner surface of the second partial ring 420. The fourth surface 540 may not be in contact with the second partial ring 420. The fourth surface 540 may be spaced apart from the second partial ring 420. The fourth surface 540 may be spaced apart from the second partial ring 420 by a second spacing G2.

The fifth surface 550 may be connected to the fourth surface 540. In addition, the fifth surface 550 may be connected to the first surface 510. The fifth surface 550 may extend so as to have a longitudinal direction parallel to the first direction D1 or the second direction D2. The fifth surface 550 may be in contact with the second partial ring 420. The fifth surface 550 may be in contact with the recessed portion of the second partial ring 420. The fifth surface 550 may be in contact with a third surface 423 as an inner surface of the second partial ring 420.

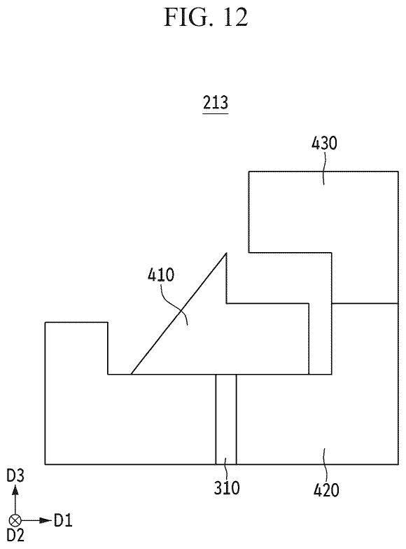

FIG. 12 is a first example diagram illustrating an operating principle of the first partial ring included in the focus ring according to one or more embodiments of the present disclosure. Referring to FIG. 12, the lift pin 310 may pass through the second partial ring 420. The lift pin 310 may sequentially pass through the base plate 211 and the chucking plate 212, and then through the second partial ring 420. The lift pin 310 may be in contact with a bottom surface of the first partial ring 410. The lift pin 310 may move the first partial ring 410 in the third direction D3. The lift pin 310 may vertically move the first partial ring 410.

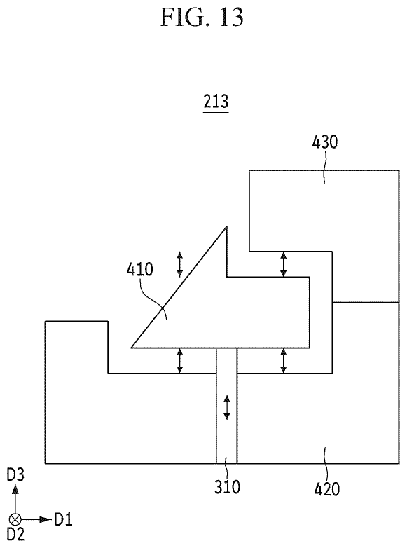

FIG. 13 is a second example diagram illustrating an operating principle of a first partial ring included in a focus ring according to one or more embodiments of the present disclosure. The focus ring 213 may include not only the first partial ring 410 but also the second partial ring 420 and the third partial ring 430. The lift pin 310 may vertically move the first partial ring 410, but may not vertically move the second partial ring 420 and the third partial ring 430. The second partial ring 420 may be secured to the surface of the chucking plate 212. The second partial ring 420 may prevent the chucking plate 212 from being etched. The third partial ring 430 may be coupled to the second partial ring 420. The third partial ring 430 may be in surface contact with the second partial ring 420. The second partial ring 420 and the third partial ring 430 may constitute an RF path.

When the focus ring 213 is formed in the structure as described with reference to FIGS. 10 and 11, four capacitances C1, C2, C3, and C4, such as a first capacitance C1, a second capacitance C2, a third capacitance C3, and a fourth capacitance C4, may be generated between the first partial ring 410, the second partial ring 420, and the third partial ring 430.

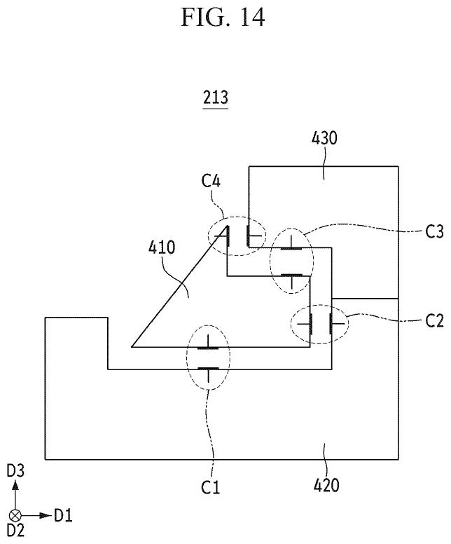

FIG. 14 is an example diagram illustrating capacitance generated between partial rings included in a focus ring according to one or more embodiments of the present disclosure. Referring to FIG. 14, a first capacitance C1 and a second capacitance C2 may be generated between the first partial ring 410 and the second partial ring 420. The third capacitance C3 and the fourth capacitance C4 may be generated between the first partial ring 410 and the third partial ring 430.

The first capacitance C1 may be generated between the fifth surface 550 of the first partial ring 410 and the third surface 423 of the second partial ring 420. The second capacitance C2 may be generated between the fourth surface 540 of the first partial ring 410 and the second surface 422 of the second partial ring 420. The third capacitance C3 may be generated between the third surface 530 of the first partial ring 410 and the second surface 432 of the third partial ring 430. The fourth capacitance C4 may be generated between the second surface 520 of the first partial ring 410 and the first surface 431 of the third partial ring 430.

In such a structure of the focus ring 213, when the first partial ring 410 moves upwardly within the space surrounded with the second partial ring 420 and the third partial ring 430, the first capacitance C1 may decrease, while the third capacitance C3 may increase. Therefore, the total capacitance (C1+C2+C3+C4) may be maintained at a predetermined level.

That is, the focus ring 213 having an equipotential structure may be constructed such that the third capacitance C3 and the fourth capacitance C4 may be further generated between the first partial ring 410 and the third partial ring 430, and the third capacitance C3 may increase when the lift pin 310 moves upwardly, such that the total capacitance may be maintained at a predetermined level. The focus ring 213 having an equipotential structure may be controlled so that the total capacitance does not decrease even when the first capacitance C1 generated between the first partial ring 410 and the second partial ring 420 decreases.

Since the total capacitance in the focus ring 213 may be maintained constant regardless of a change in the vertical level of the focus ring 213 according to the vertical movement of the lift pin 310, the coupling voltage at the focus ring 213 may also be maintained constant. Therefore, in accordance with the present disclosure, the SCD can be physically changed and the SCD change sensitivity may be improved. In addition, an effect of improving an etching rate in the edge area of the substrate W by increasing the coupling voltage may be obtained.

In summary, in a situation in which the SCD change sensitivity becomes unstable, the total capacitance is kept constant regardless of the change in the vertical level of the focus ring 213, thereby physically controlling the SCD and stabilizing the SCC change sensitivity. In addition, regarding in a situation in which process degradation occurs in the edge area of the substrate W, the coupling voltage at the focus ring 213 may be increased by maintaining a predetermined level of the total capacitance, and the etch rate in the edge area of the substrate W may be improved.

The first partial ring 410, the second partial ring 420, and the third partial ring 430 may be made of the same material. The first partial ring 410, the second partial ring 420, and the third partial ring 430 may include silicon (Si). For example, the first partial ring 410, the second partial ring 420, and the third partial ring 430 may be made of silicon carbide (SiC).

However, the present disclosure is not limited thereto, and the first partial ring 410, the second partial ring 420, and the third partial ring 430 may be made of different materials. At least one of the first partial ring 410, the second partial ring 420, and the third partial ring 430 may include silicon (Si), while at least one of the first partial ring 410, the second partial ring 420, and the third partial ring 430 may not include silicon (Si). For example, one of the first partial ring 410, the second partial ring 420, and the third partial ring 430 may be made of silicon carbide (SiC), another thereof may be made of pure silicon (Si), and the other thereof may be made of yttrium oxide (Y₂O₃).

Alternatively, one of the first partial ring 410, the second partial ring 420, and the third partial ring 430 may be made of a material different from that of each of the others thereof. For example, one of the first partial ring 410, the second partial ring 420, and the third partial ring 430 may be made of pure silicon (Si), and each of the others thereof may be made of silicon carbide (SiC). Alternatively, one thereof may be made of yttrium oxide (Y₂O₃), and each of the others thereof may be made of silicon carbide (SiC).

Hereinabove, the structure of the focus ring 213 according to one or more embodiments has been described with reference to FIGS. 10 and 11. In the present disclosure, the focus ring 213 may be variously modified under the condition that an equivalent effect may be obtained. Hereinafter, this will be described.

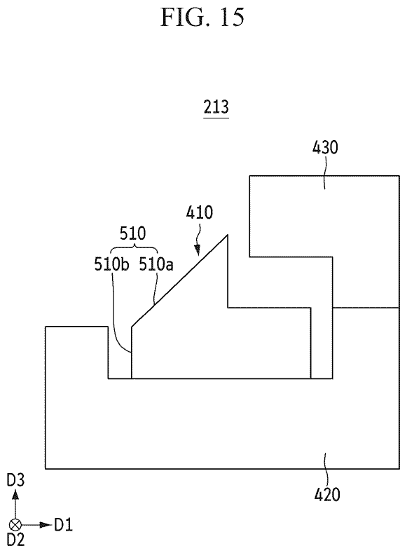

FIG. 15 is a second example diagram illustrating the structure of the focus ring according to one or more embodiments of the present disclosure. Hereinafter, a description of features similar to those described with reference to FIGS. 10 and 11 will be omitted, and only differences therebetween will be described.

The first surface 510 of the first partial ring 410 may include a first partial surface 510a and a second partial surface 510b. The first partial surface 510a may be connected to the second partial surface 510b and the second surface 520 of the first partial ring 410. The first partial surface 510a may be provided to have an inclined structure in the third direction D3. The inclination angle of the first partial surface 510a may be greater than 0 degree and smaller than 90 degrees.

The second partial surface 510b may be connected to the first partial surface 510a and the fifth surface 550 of the first partial ring 410. The second partial surface 510b may extend in a longitudinal direction parallel to the third direction D3. The second partial surface 510b may be adjacent to the first surface 421 of the second partial ring 420. The second partial surface 510b may not be in contact with the second partial ring 420. The second partial surface 510b may be spaced apart from the second partial ring 420. The second partial surface 510b may be spaced apart from the second partial ring 420 by a first spacing G1.

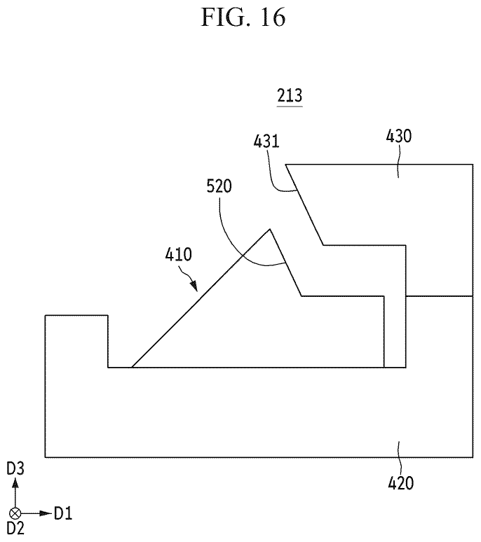

FIG. 16 is a third example diagram illustrating the structure of the focus ring according to one or more embodiments of the present disclosure. Hereinafter, a description of features similar to those described with reference to FIGS. 10 and 11 will be omitted, and only differences therebetween will be described.

The second surface 520 of the first partial ring 410 may be provided to have an inclined structure in the third direction D3. The inclination angle of the second surface 520 of the first partial ring 410 may be greater than 0 degree and smaller than 90 degrees. The second surface 520 of the first partial ring 410 may be oriented to face in a direction opposite to a direction toward the substrate W in the process chamber 200. The second surface 520 of the first partial ring 410 may not be in contact with the first surface 431 of the third partial ring 430.

The first surface 431 of the third partial ring 430 may be provided to have an inclined structure in the third direction D3. The inclination angle of the first surface 431 of the third partial ring 430 may be greater than 0 degree and smaller than 90 degrees. The inclination angle of the first surface 431 of the third partial ring 430 may be equal to, but not limited to, the inclination angle of the second surface 520 of the first partial ring 410. The first surface 431 of the third partial ring 430 may extend in a longitudinal direction parallel to the second surface 520 of the first partial ring 410. The second surface 520 of the first partial ring 410 may be spaced apart from the first surface 431 of the third partial ring 430 by a third spacing G3. However, the present disclosure is not limited thereto, and the second surface 520 of the first partial ring 410 may be spaced apart from the first surface 431 of the third partial ring 430 by a spacing Greater than the third spacing G3.

In this manner, the focus ring 213 is formed in such a structure. In this case, when the first partial ring 410 moves upwardly according to the control of the lift pin 310, the first capacitance C1 may decrease, while the third capacitance C3 and the fourth capacitance C4 may increase. The total capacitance (C1+C2+C3+C4) may be maintained at a predetermined level, or may be further increased beyond the predetermined level. The coupling voltage at the focus ring 213 may be further increased, and the etch rate in the edge area of the substrate W may be further improved.

In one or more embodiments, the focus ring 213 may include both the structure as described with reference to FIG. 15 and the structure as described with reference to FIG. 16.

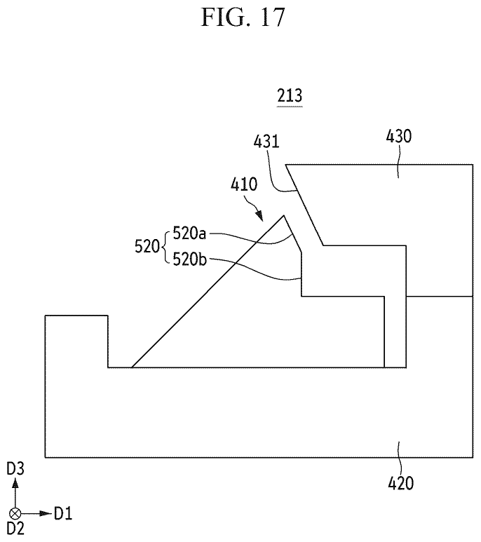

FIG. 17 is a fourth example diagram illustrating the structure of the focus ring according to one or more embodiments of the present disclosure. Hereinafter, a description of features similar to those described with reference to FIGS. 10 and 11 will be omitted, and only differences therebetween will be described.

The second surface 520 of the first partial ring 410 may include a third partial surface 520a and a fourth partial surface 520b. The third partial surface 520a may be connected to the first surface 510 and the fourth partial surface 520b of the first partial ring 410. The third partial surface 520a may be provided to have an inclined structure in the third direction D3. The inclination angle of the third partial surface 520a may be greater than 0 degree and smaller than 90 degrees. The third partial surface 520a may be oriented to face in a direction opposite to a direction toward the substrate W in the process chamber 200.

The fourth partial surface 520b may be connected to the third surface 530 and the third partial surface 520a of the first partial ring 410. The fourth partial surface 520b may extend in a longitudinal direction parallel to the third direction D3.

The first surface 431 of the third partial ring 430 may be formed in a structure corresponding to a structure of the third partial surface 520a. The first surface 431 of the third partial ring 430 may be provided to have an inclined structure in the third direction D3. The inclination angle of the first surface 431 of the third partial ring 430 may be greater than 0 degree and smaller than 90 degrees. The inclination angle of the first surface 431 of the third partial ring 430 may be equal to, but not limited to, the inclination angle of the third partial surface 520a of the first partial ring 410.

The third partial surface 520a of the first partial ring 410 may not be in contact with the first surface 431 of the third partial ring 430. The third partial surface 520a of the first partial ring 410 may be spaced apart from the first surface 431 of the third partial ring 430. The third partial surface 520a of the first partial ring 410 may be spaced apart from the first surface 431 of the third partial ring 430 by a third spacing G3. However, the present disclosure is not limited thereto, and the third partial surface 520a of the first partial ring 410 may be spaced apart from the first surface 431 of the third partial ring 430 by a spacing greater than the third spacing G3.

When the focus ring 213 is formed in such a structure, the fourth capacitance C4 may be generated between the third partial surface 520a of the first partial ring 410 and the first surface 431 of the third partial ring 430. When the first partial ring 410 moves upwardly according to the control of the lift pin 310, the first capacitance C1 may decrease, while the third capacitance C3 and the fourth capacitance C4 may increase. The total capacitance (C1+C2+C3+C4) may be maintained at a predetermined level, or may be further increased beyond the predetermined level. The coupling voltage at the focus ring 213 may be further increased, and the etch rate in the edge area of the substrate W may be further improved.

In one or more embodiments, the focus ring 213 may include both the structure as described above with reference to FIG. 15 and the structure as described above with reference to FIG. 17. Alternatively, the focus ring 213 may include both the structure as described above with reference to FIG. 16 and the structure as described above with reference to FIG. 17. Alternatively, the focus ring 213 may include all of the structure as described above with reference to FIG. 15, the structure as described above with reference to FIG. 16, and the structure as described above with reference to FIG. 17.

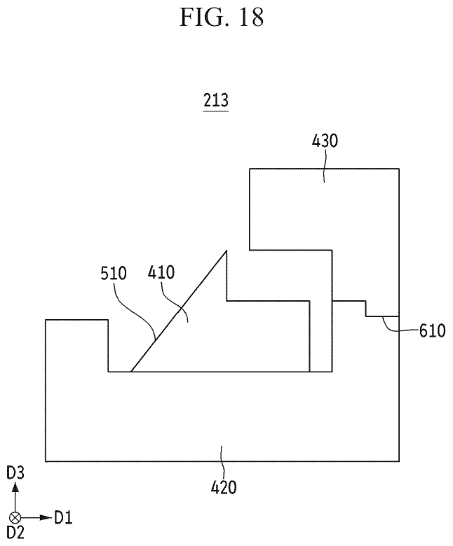

FIG. 18 is a fifth example diagram illustrating the structure of the focus ring according to one or more embodiments of the present disclosure. Hereinafter, a description of features similar to those described with reference to FIGS. 10 and 11 will be omitted, and only differences therebetween will be described.

As described above, in order to form the RF path, the second partial ring 420 and the third partial ring 430 may be in surface contact with each other. In this regard, the contact surface between the second partial ring 420 and the third partial ring 430 may be provided as a flat surface. However, the present disclosure is not limited thereto, and the contact surface may be provided as a non-flat surface 610. When the contact surface between the second partial ring 420 and the third partial ring 430 is provided as the non-flat surface, the bonding force between the second partial ring 420 and the third partial ring 430 may be improved. The contact surface between the second partial ring 420 and the third partial ring 430 may be formed in rear of the first partial ring 410. A spacing between the contact surface between the second partial ring 420 and the third partial ring 430 and the substrate W may be larger than a spacing between the first partial ring 410 and the substrate W. When the contact surface between the second partial ring 420 and the third partial ring 430 is formed as described above, the first surface 510 of the first partial ring 410 may be exposed toward the substrate W.

In one or more embodiments, the focus ring 213 may include both the structure as described above with reference to FIG. 15 and the structure as described above with reference to FIG. 18. Alternatively, the focus ring 213 may include both the structure as described above with reference to FIG. 16 and the structure as described above with reference to FIG. 18. Alternatively, the focus ring 213 may include both the structure as described above with reference to FIG. 17 and the structure as described above with reference to FIG. 18. Alternatively, the focus ring 213 may include all of the structure as described above with reference to FIG. 15, the structure as described above with reference to FIG. 16, and the structure as described above with reference to FIG. 18. Alternatively, the focus ring 213 may include all of the structure as described above with reference to FIG. 15, the structure as described above with reference to FIG. 17, and the structure as described above with reference to FIG. 18. Alternatively, the focus ring 213 may include all of the structure as described above with reference to FIG. 16, the structure as described above with reference to FIG. 17, and the structure as described above with reference to FIG. 18. Alternatively, the focus ring 213 may include all of the structure as described above with reference to FIG. 15, the structure as described above with reference to FIG. 16, the structure as described above with reference to FIG. 17, and the structure as described above with reference to FIG. 18.

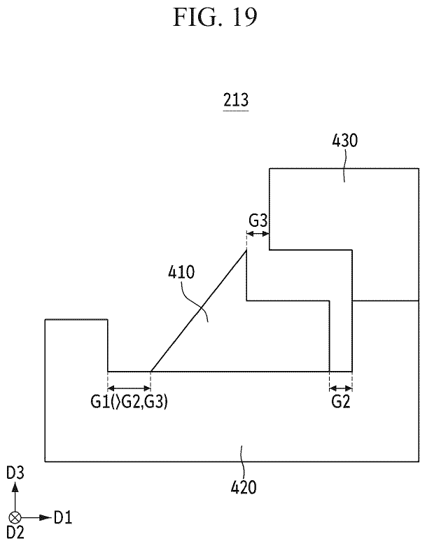

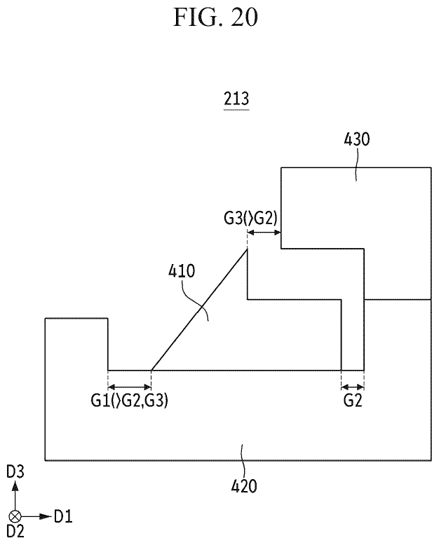

FIG. 19 is a sixth example diagram illustrating the structure of the focus ring according to one or more embodiments of the present disclosure. FIG. 20 is a seventh example diagram illustrating the structure of the focus ring according to one or more embodiments of the present disclosure. Hereinafter, a description of features similar to those described with reference to FIGS. 10 and 11 will be omitted, and only differences therebetween will be described.

A first spacing G1 may be defined between the first surface 510 of the first partial ring 410 and the second partial ring 420. A second spacing G2 may be defined between the fourth surface 540 of the first partial ring 410 and the second partial ring 420. A third spacing G3 may be defined between the second surface 520 of the first partial ring 410 and the third partial ring 430.

The first spacing G1, the second spacing G2, and the third spacing G3 may be equal to each other. However, the present disclosure is not limited thereto, and any one of the first spacing G1, the second spacing G2, and the third spacing G3 may be different from the others thereof. For example, referring to FIG. 19, the first spacing G1 be greater than each of the second spacing G2 and the third spacing G3. The second spacing G2 and the third spacing G3 may be equal to each other. Alternatively, all of the first spacing G1, the second spacing G2, and the third spacing G3 may be different from each other. For example, referring to FIG. 20, the first spacing G1 may be greater than each of the second spacing G2 and the third spacing G3. The third spacing G3 may be greater than the second spacing G2.

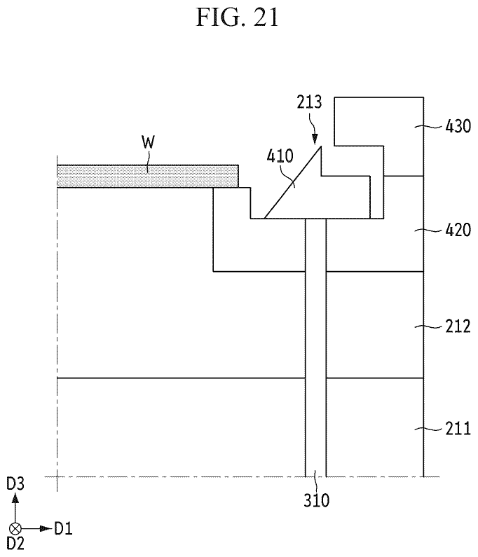

FIG. 21 is a partial cross-sectional view of a substrate support including a focus ring according to one or more embodiments of the present disclosure. The focus ring 213 may be formed on an edge area of the chucking plate 212. The focus ring 213 may be adjacent to the substrate W. The substrate W may be in contact with the second partial ring 420. The lift pin 310 may pass through the base plate 211, the chucking plate 212, and the second partial ring 420. The lift pin 310 may vertically move the first partial ring 410.

The focus ring 213 may include an equipotential structure. The focus ring 213 may include the first partial ring 410, the second partial ring 420, and the third partial ring 430. The first partial ring 410 may be provided as an inner focus ring. The first partial ring 410 may be connected to the lift pin 310. The first partial ring 410 may move in the vertical direction in the inner space defined by the second partial ring 420 and the third partial ring 430. The inner wall of the first partial ring 410 may be formed to have an inclination at a predetermined angle. The inner wall of the first partial ring 410 may be formed to be inclined. The inner wall of the first partial ring 410 may minimize sheathing distortion.

The second partial ring 420 may be provided as an under focus ring. The second partial ring 420 may be located on a shoulder of the chucking plate 212.

The third partial ring 430 may be provided as an upper focus ring. The third partial ring 430 may cover a recessed upper surface of the first partial ring 410. To form the RF path RF Path, the outermost portions of the second partial ring 420 and the third partial ring 430 may be in surface contact with each other. In order to enable the vertical movement of the first partial ring 410, the inner diameter of the third partial ring 430 may be greater than the inner diameter of the second partial ring 420.

The first partial ring 410, the second partial ring 420, and the third partial ring 430 may be made of the same material. For example, the first partial ring 410, the second partial ring 420, and the third partial ring 430 may be made of silicon carbide (SiC). The focus ring 213 may maximize RF coupling.

The first partial ring 410 may be spaced apart from the second partial ring 420 by a first spacing G1. The first partial ring 410 may be spaced apart from the second partial ring 420 by a second spacing G2. The first partial ring 410 may be spaced apart from the third partial ring 430 by a third spacing G3. Specifically, the first surface 510 of the first partial ring 410 may be spaced apart from the first surface 421 of the second partial ring 420 by a first spacing G1. The fourth surface 540 of the first partial ring 410 may be spaced apart from the second surface 422 of the second partial ring 420 by a second spacing G2. The second surface 520 of the first partial ring 410 may be spaced apart from the first surface 431 of the third partial ring 430 by a third spacing G3. The first spacing G1, the second spacing G2, and the third spacing G3 may prevent micro arcing.

Although one or more non-limiting embodiments of the present disclosure have been described with reference to the accompanying drawings, the present disclosure is not limited to the above embodiments, but may be implemented in various different forms. A person or ordinary skill in the art may appreciate that the present disclosure may be practiced in other concrete forms without changing the technical concept or characteristics of the present disclosure. Therefore, it should be appreciated that the embodiments as described above are not restrictive but illustrative in all respects.

What is claimed is:

1. A substrate treating apparatus comprising:
a chamber housing;
a substrate support in the chamber housing and configured to support a substrate, wherein the substrate support comprises a focus ring surrounding a space configured to support the substrate;
a process gas supply configured to supply a process gas into the chamber housing; and
a plasma generator configured to generate plasma using an electrode in the chamber housing,
wherein the focus ring comprises:
a second partial ring;
a first partial ring on the second partial ring, the first partial ring comprising an inclined surface; and
a third partial ring on the second partial ring and spaced apart from the first partial ring.

2. The substrate treating apparatus of claim 1, wherein the first partial ring is vertically movable relative to the substrate support.

3. The substrate treating apparatus of claim 2, wherein a change in a distance between the first partial ring and the second partial ring caused by vertical movement of the first partial ring is inversely proportional to a change in a distance between the first partial ring and the third partial ring caused by vertical movement of the first partial ring.

4. The substrate treating apparatus of claim 2, further comprising a lift pin configured to vertically move the first partial ring,
wherein the lift pin passes through the second partial ring.

5. The substrate treating apparatus of claim 2, wherein the second partial ring and the third partial ring are fixed relative to the substrate support.

6. The substrate treating apparatus of claim 1, wherein the third partial ring is in surface contact with the second partial ring.

7. The substrate treating apparatus of claim 1, wherein the second partial ring comprises a recessed portion, and the first partial ring is in an inner space defined by the recessed portion.

8. The substrate treating apparatus of claim 7, wherein the first partial ring is not in contact with an inner side surface of the second partial ring.

9. The substrate treating apparatus of claim 1, wherein the substrate support comprises:
a base plate; and
a chucking plate on the base plate, and
wherein the focus ring is along an edge of the chucking plate.

10. The substrate treating apparatus of claim 1, wherein the first partial ring comprises:
a fifth surface constituting a lower surface of the first partial ring;
a first surface connected to one end of the fifth surface and comprising the inclined surface;
a fourth surface connected to another end of the fifth surface and extending in a third direction;
a third surface connected to the fourth surface and extending in a first direction perpendicular to the third direction and extending toward the first surface; and
a second surface connected to the first surface and the third surface and extending in the third direction.

11. The substrate treating apparatus of claim 10, wherein the second surface is not in contact with a front surface of the third partial ring.

12. The substrate treating apparatus of claim 10, wherein the second surface comprises an inclined surface.

13. The substrate treating apparatus of claim 12, wherein an inclination direction of the inclined surface of the second surface is different from an inclination direction of the inclined surface of the first surface.

14. The substrate treating apparatus of claim 12, wherein a front surface of the third partial ring comprises a surface facing the inclined surface of the second surface.

15. The substrate treating apparatus of claim 1, wherein each of the first partial ring, the second partial ring, and the third partial ring comprises a material selected from silicon, silicon carbide, and yttrium oxide.

16. The substrate treating apparatus of claim 1, wherein the third partial ring at least partially covers a recessed upper surface of the first partial ring.

17. A substrate treating apparatus comprising:
a chamber housing;
a substrate support in the chamber housing and configured to support a substrate;
a process gas supply configured to supply a process gas into the chamber housing; and
a plasma generator configured to generate plasma using an electrode in the chamber housing,
wherein the substrate support comprises:
a base plate;
a chucking plate on the base plate; and
a focus ring along an edge of the chucking plate, and
wherein the focus ring comprises:
a second partial ring;
a first partial ring on the second partial ring, the first partial ring comprising an inclined surface; and
a third partial ring on the second partial ring and spaced apart from the first partial ring.

18. The substrate treating apparatus of claim 17,
wherein a first spacing between the first partial ring and the second partial ring increases or decreases as the first partial ring moves vertically relative to the substrate support, and
wherein a second spacing between the first partial ring and the third partial ring increases or decreases as the first partial ring moves vertically relative to the substrate support.

19. The substrate treating apparatus of claim 18, wherein a change in the second spacing caused by vertical movement of the first partial ring is inversely proportional to a change in the first spacing caused by vertical movement of the first partial ring.

20. A substrate treating apparatus comprising:
a chamber housing;
a substrate support in the chamber housing and configured to support a substrate, wherein the substrate support comprises a focus ring surrounding a space configured to support the substrate;
a process gas supply configured to supply a process gas into the chamber housing; and
a plasma generator configured to generate plasma using an electrode in the chamber housing,
wherein the focus ring comprises:
a second partial ring;
a first partial ring on the second partial ring, the first partial ring comprising an inclined surface; and
a third partial ring on the second partial ring and spaced apart from the first partial ring,
wherein the substrate treating apparatus further comprises a lift pin configured to vertically move the first partial ring,
wherein a first spacing between the first partial ring and the second partial ring increases or decreases as the first partial ring moves vertically relative to the substrate support,
wherein a second spacing between the first partial ring and the third partial ring increases or decreases as the first partial ring moves vertically relative to the substrate support, and
wherein decrease change in the second spacing caused by vertical movement of the first partial ring is inversely proportional to decrease change in the first spacing caused by vertical movement of the first partial ring.
